(19) United States
(12) Patent Application Publication
(10) Pub. No.: US 2016/0064193 A1
(43) Pub. Date: Mar. 3, 2016

(54) SEMICONDUCTOR MANUFACTURING APPARATUS AND METHOD OF MANUFACTURING SEMICONDUCTOR DEVICE USING THE SAME

(71) Applicants: Hogon KIM, Hwaseong-si (KR); Hyunsu KIM, Suwon-si (KR); Jang-Hee LEE, Yongin-si (KR); Gilheyun CHOI, Seoul (KR); Jongwon HONG, Hwaseong-si (KR)

(72) Inventors: Hogon KIM, Hwaseong-si (KR); Hyunsu KIM, Suwon-si (KR); Jang-Hee LEE, Yongin-si (KR); Gilheyun CHOI, Seoul (KR); Jongwon HONG, Hwaseong-si (KR)

(21) Appl. No.: 14/734,183

(22) Filed: Jun. 9, 2015

(30) Foreign Application Priority Data
Sep. 3, 2014 (KR) 10-2014-0117147

(51) Int. Cl. H01J 37/32

(52) U.S. Cl. CPC H01J 37/32183; H01J 37/32091; H01J 37/32165; H01J 2237/332

(57) ABSTRACT

A semiconductor manufacturing apparatus includes a lower electrode, an upper electrode, first and second high-frequency power sources, and a controller. The lower electrode is disposed in a process chamber, and the upper electrode is disposed over the lower electrode in the process chamber. The first high-frequency power source is connected to one of the lower electrode and the upper electrode, and the second high-frequency power source is connected to one of the lower electrode and the upper electrode. The controller is connected to the first and second high-frequency power sources. The first high-frequency power source generates a first high-frequency power used to perform a first capacitively coupled plasma (CCP) process. The second high-frequency power source generates a second high-frequency power used to perform a second CCP process. The controller controls the second high-frequency power source to interrupt the second high-frequency power during the first CCP process.

### CROSS-REFERENCE TO RELATED APPLICATION

This application claims priority from Korean Patent Application No. 10-2014-0117147, filed on Sep. 3, 2014 in the Korean Intellectual Property Office, the disclosure of which is hereby incorporated by reference in its entirety.

### BACKGROUND

1. Field

Apparatus and methods consistent with exemplary embodiments relate to a semiconductor manufacturing apparatus and a method of manufacturing a semiconductor device using the same.

2. Description of the Related Art

Semiconductor devices are widely used in an electronic industry because of their small sizes, multi-functions, and/or low manufacturing costs. Semiconductor devices may be manufactured using various semiconductor manufacturing processes such as deposition processes, ion implantation processes, photolithography processes, and/or etching processes. Some of the semiconductor manufacturing processes may be performed using plasma. As semiconductor devices become more highly integrated, structures of semiconductor devices become more complex. In particular, semiconductor devices with more complex structures have been developed recently, so manufacturing processes of semiconductor devices have become more complicated and manufacturing times of semiconductor devices have increased.

### SUMMARY

One or more exemplary embodiments provide a semiconductor manufacturing apparatus capable of increasing efficiency of a semiconductor manufacturing process and a method of manufacturing a semiconductor device using the same.

One or more exemplary embodiments also provide a semiconductor manufacturing apparatus capable of improving reliability of a semiconductor manufacturing process and a method of manufacturing a semiconductor device using the same.

One or more exemplary embodiments also provide a semiconductor manufacturing apparatus capable of reducing a manufacturing time of a semiconductor device and a method of manufacturing a semiconductor device using the same.

According to an aspect of an exemplary embodiment, there is provided a semiconductor manufacturing apparatus including a process chamber including an inner space; a lower electrode disposed in the process chamber and having a top surface on which a substrate is loaded; an upper electrode disposed over the lower electrode in the process chamber; a first high-frequency power source connected to one of the lower electrode and the upper electrode, the first high-frequency power source generating a first high-frequency power used to perform a first capacitively coupled plasma (CCP) process; a second high-frequency power source connected to one of the lower electrode and the upper electrode, the second high-frequency power source generating a second high-frequency power used to perform a second CCP process; and a controller connected to the first high-frequency power source and the second high-frequency power source, wherein the controller controls the second high-frequency power source to interrupt the second high-frequency power during the first CCP process.

The controller may be configured to control the first high-frequency power source to interrupt the first high-frequency power during the second CCP process.

The first high-frequency power source may be configured to generate the first high-frequency power at a first high frequency, the second high-frequency power source may be configured to generate the second high-frequency power at a second high frequency, and the first high frequency is different from the second high frequency.

Each of the first high frequency and the second high frequency may be about 5 MHz or more.

The semiconductor manufacturing apparatus may further include a low-frequency power source connected to the controller and one of the lower electrode and the upper electrode, wherein the first high-frequency power source may be configured to generate the first high-frequency power at a first high frequency, the second high-frequency power source may be configured to generate the second high-frequency power at a second high frequency, and the low-frequency power source may be configured to generate low-frequency power at a frequency that is smaller than frequencies of the first and second high-frequency powers.

One of the lower electrode and the upper electrode may be connected to the first high-frequency power source and the second high-frequency power source, and the semiconductor manufacturing apparatus may further include a ground source connected to the other one of the lower electrode and the upper electrode.

The low-frequency power source may be connected to the other one of the lower electrode and the upper electrode, and the semiconductor manufacturing apparatus may further include a high-pass filter connected between the ground source and the other one of the lower electrode and the upper electrode, wherein the high-pass filter may be configured to pass the first high-frequency power and the second high-frequency power and substantially block the low-frequency power.

One of the lower electrode and the upper electrode may be connected to the first high-frequency power source, and the other one of the lower electrode and the upper electrode may be connected to the second high-frequency power source, and the semiconductor manufacturing apparatus may further include a first ground source; a first switch connected between the first ground source and the lower electrode; a second ground source; a second switch connected between the second ground source and the upper electrode; and a high-pass filter connected between the first ground source and the first switch, or between the second ground source and the second switch, wherein the low-frequency power source is connected to the one of the lower electrode and the upper electrode that is coupled to the high-pass filter, and wherein the high-pass filter is configured to pass the first high-frequency power and the second high-frequency power and substantially block the low-frequency power.

The process chamber may include a top plate, and the upper electrode may include a first electrode extending from the inner space of the process chamber to an outside of the process chamber, the first electrode penetrating the top plate such that a portion of the first electrode is disposed in the inner space and a portion of the first electrode is disposed outside of the process chamber; and a second electrode surrounding a sidewall of the portion of the first electrode that is disposed in the inner space, wherein the second electrode is insulated from the first electrode, wherein the first high-frequency power source is connected to the second electrode, and wherein the second high-frequency power source is connected to the portion of the first electrode disposed outside the process chamber.

The low-frequency power may be used during the first CCP process or the second CCP process.

The low-frequency power, and one of the first high-frequency power and the second high-frequency power may be used to perform a third CCP process.

The semiconductor manufacturing apparatus may be configured to perform the first CCP process and the second CCP process in-situ in the process chamber.

The first CCP process is a first CCP deposition process for depositing a first layer at a first deposition rate, wherein the second CCP process is a second CCP deposition process for depositing a second layer at a second deposition rate, and the first deposition rate is different from the second deposition rate.

The first high-frequency power has a first high frequency and the second high-frequency power has a second high frequency, wherein the second high frequency is greater than the first high frequency, and the second deposition rate is greater than the first deposition rate.

The first high-frequency power has a first high frequency and the second high-frequency power has a second high frequency, wherein the second high frequency is greater than the first high frequency, and the semiconductor manufacturing apparatus is configured such that a hydrogen content of the second layer is lower than a hydrogen content of the first layer.

The semiconductor manufacturing apparatus may be configured such that one of the first layer and the second layer has a compressive stress, and the other of the first layer and the second layer has a tensile stress.

According to an aspect of another exemplary embodiment, there is provided a method of manufacturing a semiconductor device, the method including loading a substrate on a lower electrode disposed in a process chamber, an upper electrode disposed over the lower electrode in the process chamber; depositing a first layer on the substrate using a first high-frequency power generated from a first high-frequency power source connected to one of the lower electrode and the upper electrode; and depositing a second layer on the substrate using a second high-frequency power generated from a second high-frequency power source connected to one of the lower electrode and the upper electrode, wherein a first high frequency of the first high-frequency power is different from a second high frequency of the second high-frequency power, wherein the first layer and the second layer are deposited in-situ in the process chamber, the second high-frequency power is interrupted when the first layer is deposited, and the first high-frequency power is interrupted when the second layer is deposited.

A low-frequency power source is connected to one of the lower electrode and the upper electrode, and a low frequency of a low-frequency power generated from the low-frequency power source is smaller than the first high frequency and the second high frequency.

The low-frequency power is used when the first layer or the second layer is deposited.

The method may further include depositing a third layer on the substrate, wherein the third layer is deposited using the low-frequency power, and one of the first high-frequency power and the second high-frequency power, wherein the first, second, and third layers are deposited in-situ in the process chamber, and wherein a density of the third layer is higher than a density of the first layer, and a density of the third layer is higher than a density of the second layer.

According to an aspect of another exemplary embodiment, there is provided a semiconductor manufacturing apparatus including a process chamber; a first electrode disposed in the process chamber; a first high-frequency power source connected to the first electrode and configured to generate a first high-frequency power used to perform a first capacitively coupled plasma (CCP) process inside the process chamber; a second high-frequency power source connected to the first electrode and configured to generate a second high-frequency power used to perform a second CCP process inside the process chamber; and a controller that is electrically connected to the first high-frequency power source and the second high-frequency power source and configured to control the second high-frequency power source to interrupt the second high-frequency power during the first CCP process.

The controller may be configure to control the first high-frequency power source to interrupt the first high-frequency power source during the second CCP process.

The controller may be configured to shut off the second high-frequency power source during the first CCP process.

The controller may be configured to control the second high-frequency power source to substantially reduce the second high-frequency power during the first CCP process.

The semiconductor manufacturing apparatus may further include a low frequency power source that is electrically connected to the electrode and to the controller, and configured to generate a low frequency power that is smaller than the first high frequency power and smaller than the second high frequency power.

The semiconductor manufacturing apparatus may further include a second electrode configured to support a substrate to be subjected to the first CCP process.

The semiconductor manufacturing apparatus further include a second electrode and a low frequency power source that is electrically connected to the second electrode and to the controller and configured to generate a low frequency power that is smaller than the first high frequency power and smaller than the second high frequency power.

### BRIEF DESCRIPTION OF THE DRAWINGS

The above and/or other aspects will become more apparent and more readily appreciated from the following description of exemplary embodiments, taken in conjunction with the accompanying drawings in which:

FIG. 1 is a schematic diagram illustrating a semiconductor manufacturing apparatus according to an exemplary embodiment;

FIG. 2 is a graph illustrating a method of operating the semiconductor manufacturing apparatus illustrated in FIG. 1;

FIG. 3 is a cross-sectional view illustrating an exemplary embodiment of a method of manufacturing a semiconductor device using the semiconductor manufacturing apparatus of FIG. 1;

FIGS. 4 and 5 are graphs illustrating results of experiments performed using the semiconductor manufacturing apparatus of FIG. 1;

FIG. 6 is a cross-sectional view illustrating another exemplary embodiment of a method of manufacturing a semiconductor device using the semiconductor manufacturing apparatus of FIG. 1;

FIG. 7 is a schematic diagram illustrating a semiconductor manufacturing apparatus according to an exemplary embodiment;

FIG. 8 is a schematic diagram illustrating a semiconductor manufacturing apparatus according to another exemplary embodiment;

FIG. 9 is a schematic diagram illustrating a semiconductor manufacturing apparatus according to another exemplary embodiment;

FIG. 10 is a schematic diagram illustrating a semiconductor manufacturing apparatus according to another exemplary embodiment;

FIG. 11 is a schematic diagram illustrating a semiconductor manufacturing apparatus according to another exemplary embodiment; and

FIGS. 12 to 18 are cross-sectional views illustrating another embodiment of a method of manufacturing a semiconductor device using a semiconductor manufacturing apparatus according to embodiments.

### DETAILED DESCRIPTION OF EXEMPLARY EMBODIMENTS

Exemplary embodiments will now be described more fully hereinafter with reference to the accompanying drawings. It should be noted, however, that the inventive concepts are not limited to the following exemplary embodiments, and may be implemented in various forms.

The terminology used herein is for the purpose of describing particular embodiments only and is not intended to be limiting. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element, or intervening elements may be present.

Similarly, it will be understood that when an element such as a layer, region or substrate is referred to as being “on” another element, the layer, region, or substrate can be directly on the other element, or intervening elements may be present. In contrast, the term “directly” means that there are no intervening elements. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof.

Additionally, the exemplary embodiments in the detailed description will be described with sectional views as ideal exemplary views of the inventive concepts. Accordingly, shapes of the exemplary views may be modified according to manufacturing techniques and/or allowable errors. Therefore, the embodiments of the inventive concepts are not limited to the specific shape illustrated in the exemplary views, but may include other shapes that may be created according to manufacturing processes. Areas exemplified in the drawings have general properties, and are used to illustrate specific shapes of elements. Thus, shapes shown in the drawings should not be construed as limiting the scope of the inventive concepts.

It will be also understood that although the terms “first”, “second”, “third”, etc. may be used herein to describe various elements, these elements should not be limited by these terms. Rather, these terms are only used to distinguish one element from another element. Thus, a “first” element in some exemplary embodiments could be termed a “second” element in other embodiments without departing from the teachings of the present invention. Exemplary embodiments of aspects of the present inventive concepts explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of the inventive concepts.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

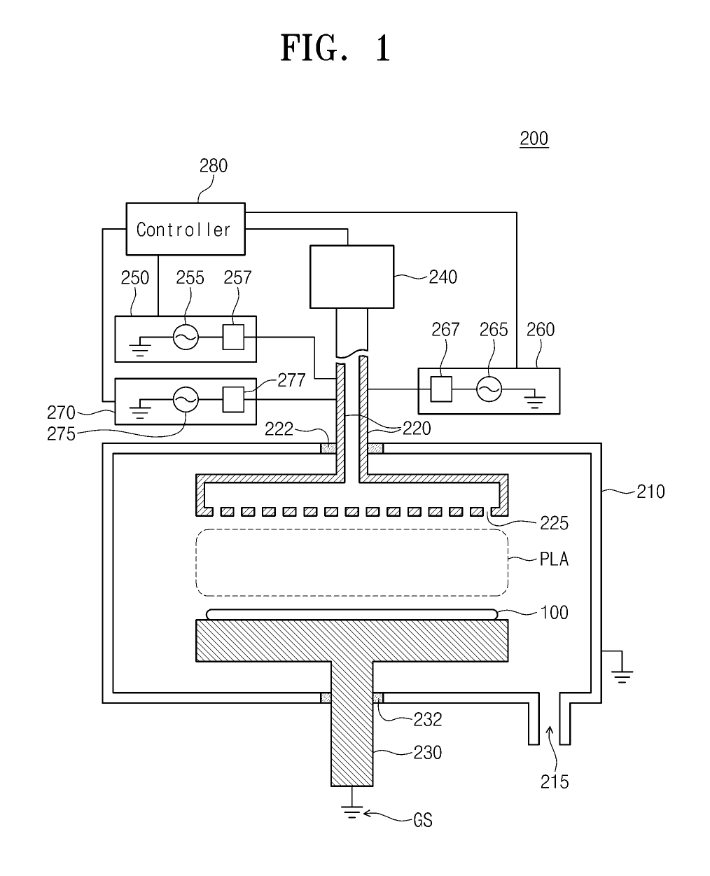

FIG. 1 is a schematic diagram illustrating a semiconductor manufacturing apparatus according to some exemplary embodiments.

Referring to FIG. 1, a semiconductor manufacturing apparatus 200 may include a process chamber 210 having an inner space in which a semiconductor process is performed. A lower electrode 230 may be disposed in the process chamber 210. The lower electrode 230 may have a top surface on which a substrate 100 is loaded. The lower electrode 230 may have an extension that penetrates a bottom plate of the process chamber 210. At least a portion of the lower electrode 230 may be formed of a conductive material (e.g., a metal such as aluminum or the like). In some exemplary embodiments, the lower electrode 230 may be a chuck. For example, the lower electrode 230 may be an electrostatic chuck (ESC) or a vacuum chuck or the like.

An upper electrode 220 may be disposed over the lower electrode 230 in the process chamber 210. The upper electrode 220 may have an extension that penetrates a top plate of the process chamber 210. The upper electrode 220 may be vertically spaced apart from the substrate 100 loaded on the lower electrode 230. In some exemplary embodiments, the upper electrode 220 may be a shower head that is used to supply a process gas into the process chamber 210. The shower head may have holes 225 for supplying the process gas into the process chamber 210. The shower head may be formed of a conductive material (e.g., a metal such as aluminum or the like).

In some exemplary embodiments, the process chamber 210 may be formed of a conductive material (e.g., a metal such as aluminum or the like). In this case, a first insulator 232 may be disposed between the extension of the lower electrode 230 and the bottom plate of the process chamber 210, and a second insulator 222 may be disposed between the extension of the upper electrode 220 and the top plate of the process chamber 210. In some exemplary embodiments, the process chamber 210 may be grounded while a semiconductor process is performed in the process chamber 210. The semiconductor process may be predetermined.

The process chamber 210 may be equipped with an exhaust port 215. In some exemplary embodiments, the exhaust port 215 may be connected to the bottom plate of the process chamber 210. However, this is only an example, and the location of the exhaust port 215 is not particularly limited as long as exhaust may escape from the process chamber 210 through the exhaust port 215. The exhaust port 215 may be connected to a vacuum pump, so an inner pressure of the process chamber 210 may be controlled by the exhaust port 215 and the vacuum pump. In addition, by-products and/or a residual process gas generated during the semiconductor process may be exhausted through the exhaust port 215.

A first high-frequency power unit 250 may be connected to one of the lower and upper electrodes 230 and 220. The first high-frequency power unit 250 may include a first high-frequency power source 255 that generates a first high-frequency power. In other words, the first high-frequency power source 255 may be connected to one of the lower and upper electrodes 230 and 220. The first high-frequency power provides a plasma power for generating a capacitively coupled plasma PLA. The first high-frequency power has a first high frequency. The first high-frequency power unit 250 may further include a first high-frequency matching box 257 that may be connected between the first high-frequency power source 255 and one of the lower and upper electrodes 230 and 220.

A second high-frequency power unit 260 may be connected to one of the lower and upper electrodes 230 and 220. The second high-frequency power unit 260 may include a second high-frequency power source 265 that generates a second high-frequency power. In other words, the second high-frequency power source 265 may be connected to one of the lower and upper electrodes 230 and 220. The second high-frequency power provides a plasma power for generating a capacitively coupled plasma PLA. The second high-frequency power has a second high frequency. The second high-frequency power unit 260 may further include a second high-frequency matching box 267 that may be connected between the second high-frequency power source 265 and one of the lower and upper electrodes 230 and 220.

The first high frequency of the first high-frequency power and the second high frequency of the second high-frequency power may be radio frequencies (RFs). The first high frequency of the first high-frequency power may be different from the second high frequency of the second high-frequency power. In some exemplary embodiments, each of the first and second high frequencies is 5 MHz or more. In some exemplary embodiments, the second high frequency may be greater than the first high frequency. In some exemplary embodiments, the first high frequency may be in a range of about 5 MHz to about 2.40 GHz. For example, the first high frequency may be 13.56 MHz. The second high frequency may be in a range of about 27 MHz to about 2.45 GHz. For example, the second high frequency may be 27 MHz or 27.12 MHz. For example, each of the first and second high-frequency powers may be in a range of about 100 W to about 1000 W.

A low-frequency power unit 270 may be connected to one of the lower and upper electrodes 230 and 220. The low-frequency power unit 270 may include a low-frequency power source 275. In other words, the low-frequency power source 275 may be connected to one of the lower and upper electrodes 230 and 220. The low-frequency power source 275 may generate a low-frequency power having a low frequency. The low frequency of the low-frequency power may be less than the first high frequency and the second high frequency. In some exemplary embodiments, the low frequency of the low-frequency power may be less than about 5 MHz. For example, the low frequency of the low-frequency power may be in a range of about 200 KHz to about 3 MHz. For example, the low-frequency power may be in a range of 0 W to about 500 W. The low-frequency power unit 270 may further include a low-frequency matching box 277 connected between the low-frequency power source 275 and one of the lower and upper electrodes 230 and 220.

A gas supply unit 240 may be configured to provide a process gas into the process chamber 210. In some exemplary embodiments, if the upper electrode 220 is the shower head as described above, the gas supply unit 240 may be connected to the upper electrode 220.

A controller 280 may be connected to the first and second high-frequency power units 250 and 260. In addition, the controller 280 may also be connected to the low-frequency power unit 270 and the gas supply unit 240. The controller 280 may control operations of the power units 250, 260, and 270 and the gas supply unit 240.

In this exemplary embodiment, the first and second high-frequency power units 250 and 260 and the low-frequency power unit 270 may be connected to the upper electrode 220. Thus, the first high-frequency power of the first high-frequency power source 255 may be applied to the upper electrode 220 through the first high-frequency matching box 257. The first high-frequency matching box 257 may improve transmission efficiency of the first high-frequency power. The second high-frequency power of the second high-frequency power source 265 may be applied to the upper electrode 220 through the second high-frequency matching box 267. The second high-frequency matching box 267 may improve transmission efficiency of the second high-frequency power. The low-frequency power of the low-frequency power source 275 may be applied to the upper electrode 220 through the low-frequency matching box 277. The low-frequency matching box 277 may improve transmission efficiency of the low-frequency power. In the case that the power units 250, 260, and 270 are connected to the upper electrode 220, the lower electrode 230 may be connected to a ground source GS.

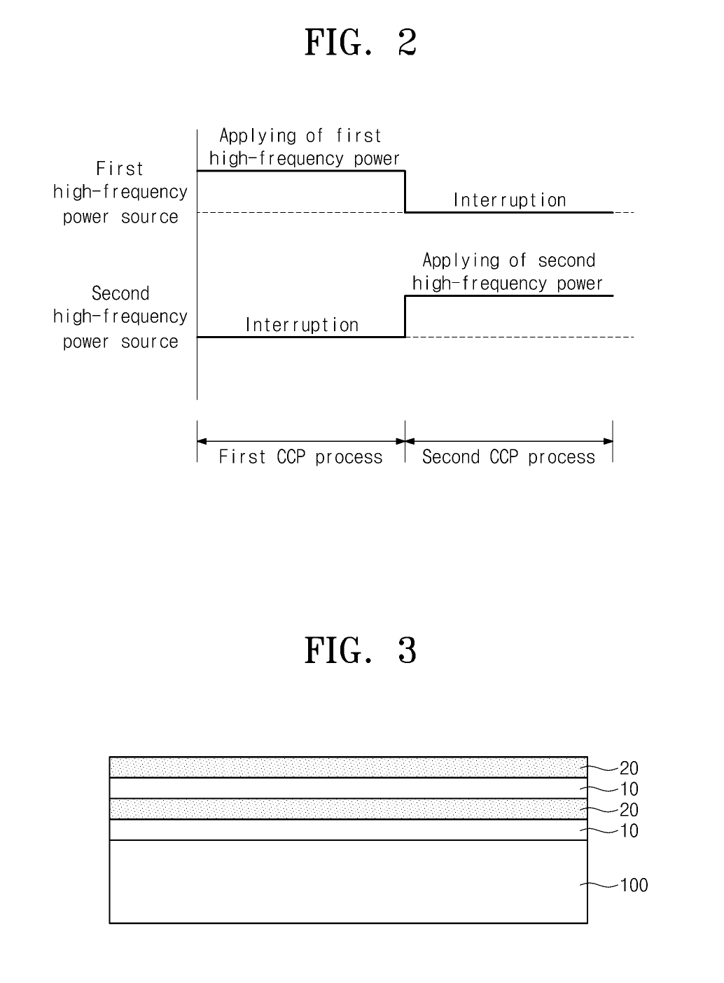

The first high-frequency power of the first high-frequency power source 255 may be used to perform a first capacitively coupled plasma (CCP) process, and the second high-frequency power of the second high-frequency power source 265 may be used to perform a second capacitively coupled plasma (CCP) process. In other words, the first high-frequency power may act as a plasma power that generates plasma PLA during the first CCP process, and the second high-frequency power may act as a plasma power that generates plasma PLA during the second CCP process. These will be described in more detail with reference to FIG. 2.

FIG. 2 is a graph illustrating a method of operating the semiconductor manufacturing apparatus illustrated in FIG. 1.

Referring to FIGS. 1 and 2, the substrate 100 may be loaded on the top surface of the lower electrode 230. The controller 280 may control the gas supply unit 240 to supply a first process gas into the process chamber 210. The controller 280 may control the first high-frequency power unit 250 to apply the first high-frequency power of the first high-frequency power source 255 to the upper electrode 220. Thus, plasma PLA may be generated over the substrate 100. The first CCP process may be performed using the plasma PLA generated by the first high-frequency power. Here, the controller 280 may interrupt the second high-frequency power of the second high-frequency power source 265 during the first CCP process. For example, the controller 280 may shut off the second high-frequency power source 265 during the first CCP process. Alternatively, the controller 280 may control the second high-frequency power source 265 to substantially decrease the power therefrom during the first CCP process. In other words, the second high-frequency power may not be used during the first CCP process.

The controller 280 may control the gas supply unit 240 to supply a second process gas into the process chamber 210 and may control the second high-frequency power unit 260 to apply the second high-frequency power of the second high-frequency power source 265 to the upper electrode 220. Thus, plasma PLA may be generated over the loaded substrate 100 and the second CCP process may be performed using the plasma PLA generated by the second high-frequency power. Here, the controller 280 may interrupt the first high-frequency power of the first high-frequency power source 255 during the second CCP process. For example, the controller 280 may shut off the first high-frequency power source 255 during the second CCP process. Alternatively, the controller 280 may control the first high-frequency power source 255 to substantially decrease the power therefrom during the first CCP process. In other words, the first high-frequency power may not be used during the second CCP process.

As a result, the second high-frequency power source 265 is not concerned with the first CCP process, and the first high-frequency power source 255 is not concerned with the second CCP process. The second process gas may be the same as the first process gas. Alternatively, the second process gas may include a material different from at least a portion of the first process gas.

In some exemplary embodiments, the low-frequency power of the low-frequency power source 275 may be used during at least one of the first and second CCP processes. The low-frequency power may control mobility of ions of the plasma PLA, and thus, characteristics of the first and/or second CCP processes may be more accurately controlled. In other embodiments, the low-frequency power of the low-frequency power source 275 may be used to perform a third CCP process. For example, the low-frequency power source 275 may be used along with the first high-frequency power and/or the second high-frequency power to perform the third CCP process. The third CCP process may be different from the first and second CCP processes.

The first and second CCP processes may be performed in-situ in the process chamber 210. For example, the second CCP process may be performed immediately after the first CCP process in the process chamber 210. Alternatively, the first CCP process may be performed immediately after the second CCP process in the process chamber 210.

Process temperatures of the first and second CCP processes may be in a range of about 350° C. to about 600° C. Process pressures of the first and second CCP processes may be in a range of about 0.1 Torr to about 100 Torr.

As described above, the semiconductor manufacturing apparatus 200 includes the first and second high-frequency power units 250 and 260 generating the first and second high frequencies, respectively, that are different from each other to sequentially perform a plurality of CCP processes using the first and second high frequencies respectively. Thus, the semiconductor manufacturing apparatus 200 may satisfy process characteristics of the plurality of CCP processes. In other words, reliability and efficiency of the semiconductor manufacturing process may be improved. In addition, since the CCP processes are performed in-situ in the process chambers 210, a process time of the semiconductor manufacturing process may be reduced to improve productivity of semiconductor devices.

In some exemplary embodiments, the first CCP process may be a first CCP deposition process for depositing a first layer, and the second CCP process may be a second CCP deposition process for depositing a second layer. These will be described in more detail with reference to FIG. 3.

FIG. 3 is a cross-sectional view illustrating an exemplary embodiment of a method of manufacturing a semiconductor device using the semiconductor manufacturing apparatus of FIG. 1.

Referring to FIGS. 1, 2, and 3, the substrate 100 may be loaded on the lower electrode 230. The gas supply unit 240 may supply a first deposition process gas into the process chamber 210, and the first high-frequency power of the first high-frequency power source 255 may be applied to the upper electrode 220. Thus, the first CCP deposition process may be performed using the plasma PLA generated over the substrate 100 to deposit a first layer 10 on the substrate 100. As described above, the second high-frequency power of the second high-frequency power source 265 is interrupted during the first CCP deposition process. The low-frequency power of the low-frequency power source 275 may be applied to or may not be applied to the upper electrode 220 during the first CCP deposition process.

The gas supply unit 240 may supply a second deposition process gas into the process chamber 210, and the second high-frequency power of the second high-frequency power source 265 may be applied to the upper electrode 220. Thus, the second CCP deposition process may be performed to deposit a second layer 20 on the first layer 10. The first high-frequency power of the first high-frequency power source 255 is interrupted during the second CCP deposition process. The low-frequency power of the low-frequency power source 275 may be applied to or may not be applied to the upper electrode 220 during the second CCP deposition process.

The first and second CCP deposition processes may be performed in-situ in the process chamber 210. As described above, the second CCP deposition process may be performed after the first CCP deposition process. Alternatively, the first CCP deposition process may be performed after the second CCP deposition process is performed.

In some exemplary embodiments, a material of the first layer 10 may be different from a material of the second layer 20. In other words, at least a portion of the second deposition process gas may be different from at least a portion of the first deposition process gas. For example, the first deposition process gas may include a silicon source gas (e.g., SiH₄ and/or SiCl₄) and an oxygen source gas (e.g., N₂O), so the first layer 10 may be formed of a silicon oxide layer. The first deposition process gas may further include an inert gas (e.g., a nitrogen (N₂) gas). For example, the second deposition process gas may include a silicon source gas (e.g., SiH₄ and/or SiCl₄) and a nitrogen source gas (e.g., NH₃), so the second layer 20 may be formed of a silicon nitride layer. The second deposition process gas may further include an inert gas (e.g., a N₂ gas). However, the inventive concepts are not limited thereto. The first and second deposition process gases may include at least one selected from various source gases. In other words, each of the first and second layers 10 and 20 may include any one of an insulating layer (e.g., a silicon oxide layer, a silicon nitride layer, a silicon oxynitride layer, a silicon carbonitride layer, a silicon carbide layer, or an amorphous carbon layer etc.) and a conductive layer (e.g., a doped semiconductor layer, a metal layer, a conductive metal nitride layer, or a conductive metal oxide layer etc.). Here, the first and second layers 10 and 20 may be formed of the same material or different materials from each other.

Since the first high frequency of the first high-frequency power is different from the second high frequency of the second high-frequency power, a deposition rate of the first layer 10 may be different from that of the second layer 20. In the case in which the second high frequency is greater than the first high frequency, the deposition rate of the second layer 20 may be higher than that of the first layer 10. Thus, a deposition time of the second layer 20 may be reduced. In addition, a density of the second layer 20 may be lower than that of the first layer 10 in the case that the second high frequency is greater than the first high frequency.

In addition, a hydrogen content of the first layer 10 may be different from that of the second layer 20. In the case in which the second high frequency is greater than the first high frequency, the hydrogen content of the second layer 20 may be lower than that of the first layer 10. Hydrogen in a layer may escape from the layer by a subsequent thermal process (e.g., a process performed at a temperature of about 600° C. or more). In such a case, a density of the layer may be reduced, so a stress of the layer may be varied to cause defects of a semiconductor device. However, according to exemplary embodiments of the inventive concepts described herein, the second CCP deposition process using the second high-frequency power can reduce the hydrogen content of the second layer 20, and thus, defects of the semiconductor device may be reduced or minimized. For example, the hydrogen content of the second layer 20 may be in a range of 0% to about 10%. The hydrogen content of the first layer 10 may also be in a range of about 0% to about 10%.

Moreover, since the second high frequency is different from the first high frequency, one of the first and second layers 10 and 20 may have a compressive stress, and the other of the first and second layers 10 and 20 may have a tensile stress. In other words, the stresses of the first and second layers 10 and 20 may offset each other, so a net stress of the first and second layers 10 and 20 may be reduced or minimized. As a result, a stress applied to the semiconductor device may be reduced to improve the reliability of the semiconductor device. For example, in the event that the second high frequency is greater than the first high frequency, the first layer 10 may have the compressive stress and the second layer 20 may have the tensile stress.

In some exemplary embodiments, as illustrated in FIG. 3, the first CCP deposition process and the second CCP deposition process may be alternately and repeatedly performed to form the first layers 10 and the second layers 20 which are alternately and repeatedly stacked on the substrate 100.

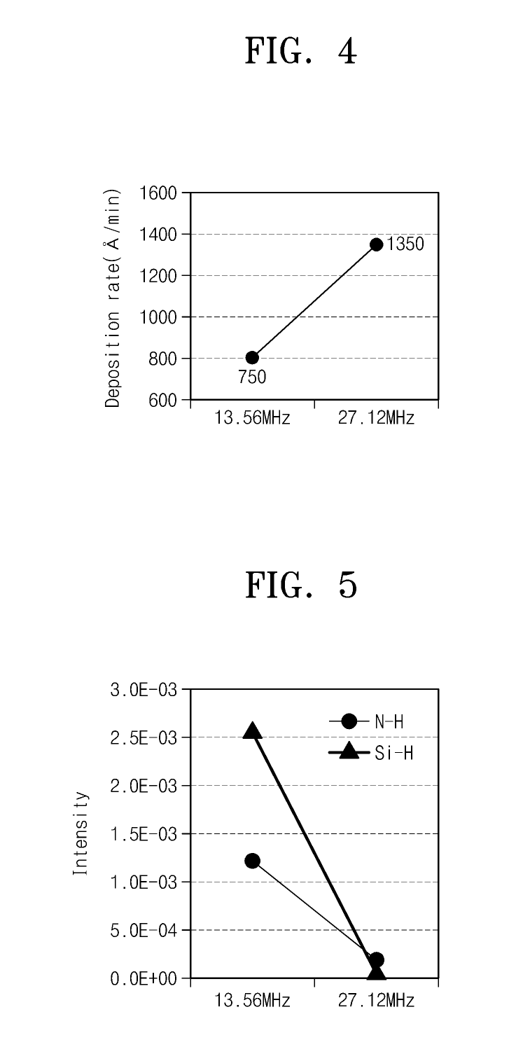

Experiments were performed to confirm characteristics of the semiconductor manufacturing apparatus 200 according to the above exemplary embodiments of the inventive concepts. These will be described with reference to FIGS. 4 and 5.

FIGS. 4 and 5 are graphs illustrating results of experiments performed using the semiconductor manufacturing apparatus of FIG. 1.

A first sample and a second sample were prepared for the experiments. The first sample was formed to include a first silicon nitride layer, and the second sample was formed to include a second silicon nitride layer. The first silicon nitride layer of the first sample was formed by a CCP deposition process using a high-frequency power having a high frequency of 13.56 MHz, and the second silicon nitride layer of the second sample was formed by a CCP deposition process using a high-frequency power having a high frequency of 27.12 MHz. As shown in FIG. 4, a deposition rate of the second silicon nitride layer of the second sample was 1350 Å/min, and a deposition rate of the first silicon nitride layer of the first sample was 750 Å/min. Thus, it is confirmed that the deposition rate of the layer increases in proportion to a frequency of the high-frequency power. This is because a degree of dissociation of the process gas increases in proportion to the frequency of the high-frequency power. In other words, the amount of silicon radicals and the amount of nitrogen radicals may be increased, so the deposition of the silicon nitride layer may be increased. The first and second silicon nitride layers of the first and second samples were analyzed by a Fourier transform infrared spectrometer (FI-IR), and the analyzed results are illustrated in FIG. 5. As shown in FIG. 5, a hydrogen content of the second silicon nitride layer formed using the frequency of 27.12 MHz is lower than that of the first silicon nitride layer formed using the frequency of 13.56 MHz. In other words, it is confirmed that the hydrogen content is reduced as the frequency of the high-frequency power increases.

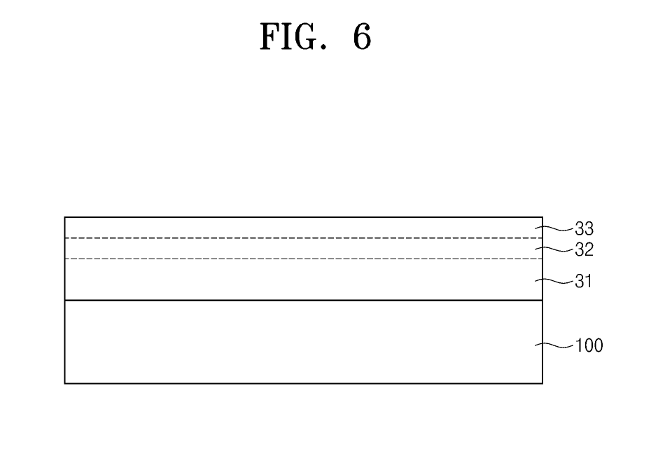

FIG. 6 is a cross-sectional view illustrating another exemplary embodiment of a method of manufacturing a semiconductor device using the semiconductor manufacturing apparatus of FIG. 1.

Referring to FIGS. 1, 2, and 6, a lower layer 31 may be deposited on the substrate 100 by the second CCP deposition process using the second high-frequency power source 265. The first high-frequency power is interrupted during the second CCP deposition process. In this exemplary embodiment, the low-frequency power of the low-frequency power source 275 may also be interrupted during the second CCP deposition process. The first CCP deposition process using the first high-frequency power source 255 may be performed to deposit a middle layer 32 on the lower layer 31. In this exemplary embodiment, the second high-frequency power and the low-frequency power may be interrupted during the first CCP deposition process. A third CCP deposition process using the first high-frequency power and the low-frequency power may be performed to deposit an upper layer 33 on the middle layer 32. The second high-frequency power is interrupted during the third CCP deposition process.

In some exemplary embodiments, the second, first, and third CCP deposition processes may use the same process gas. Thus, the lower, middle, and upper layers 31, 32, and 33 may be formed of the same material. Here, densities of the lower, middle, and upper layers 31, 32, and 33 may be different from each other. In more detail, in the case that the second high frequency is greater than the first high frequency, the density of the lower layer 31 may be lower than those of the middle and upper layers 32 and 33. In addition, since the upper layer 33 is deposited using the first high-frequency power and the low-frequency power increasing the ion mobility, the density of the upper layer 33 may be higher than that of the middle layer 32.

For example, the same process gas of the first, second, and third CCP deposition processes may include a carbon source gas (e.g., C₃H₆, C₂H₂, and/or C₃H₁₂), so the lower, middle, and upper layers 31, 32, and 33 may be amorphous carbon layers. However, the inventive concepts are not limited thereto. In other exemplary embodiments, the process gases of the first, second, and third CCP deposition processes may include at least one of other materials.

Since the lower, middle, and upper layers 31, 32, and 33 are formed of the same material but have different densities from each other, interfaces may exist between the lower, middle, and upper layers 31, 32, and 33. Alternatively, the interfaces may not exist between the lower, middle, and upper layers 31, 32, and 33.

In this exemplary embodiment, three CCP processes are performed using the first high-frequency power, the second high-frequency power, and the low-frequency power. However, the inventive concepts are not limited thereto. The first high-frequency power, the second high-frequency power, and the low-frequency power may be combined in various forms under the condition that the first high-frequency power and the second high-frequency power are not used together.

Next, semiconductor manufacturing apparatuses according to exemplary embodiments will be described. Hereinafter, the same elements as described in FIG. 1 will be indicated by the same reference numeral or the same reference designators. For the purpose of ease and convenience in explanation, the descriptions to the same elements as in the embodiment of FIG. 1 will be omitted or mentioned briefly. In other words, differences between the exemplary embodiment of FIG. 1 and other exemplary embodiments will be mainly described. Methods of operating semiconductor manufacturing apparatuses described below may be the substantially same as described with reference to FIGS. 1 to 6. However, differences between the operating method of the apparatus 200 of FIG. 1 and operating methods of the following apparatuses will be described.

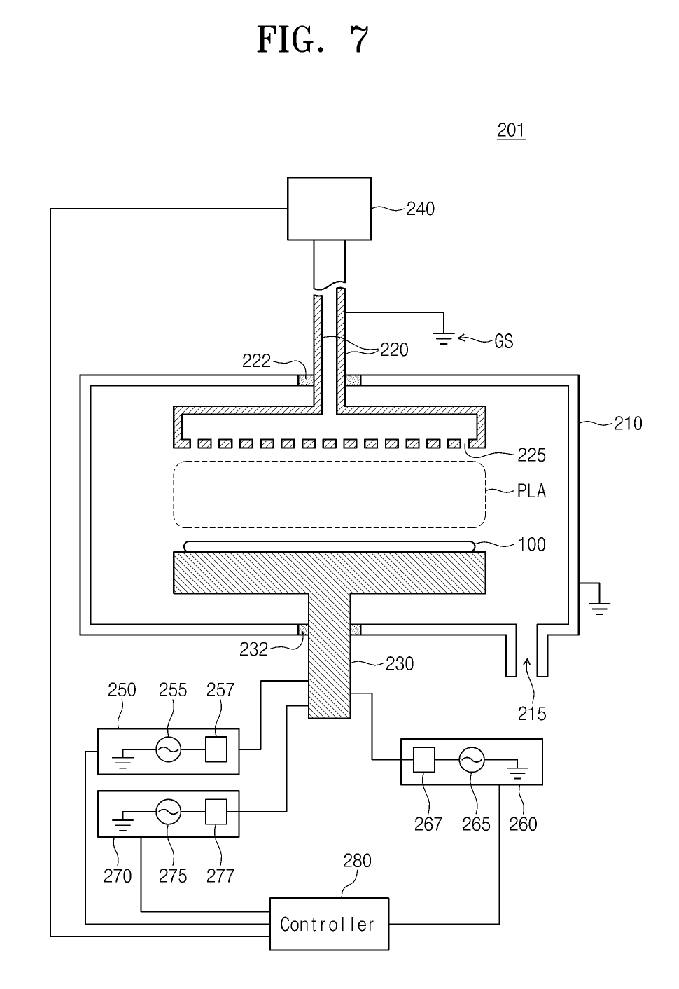

FIG. 7 is a schematic diagram illustrating a semiconductor manufacturing apparatus according to another exemplary embodiment.

Referring to FIG. 7, in a semiconductor manufacturing apparatus 201, the first and second high-frequency power units 250 and 260 and the low-frequency power unit 270 may be connected to the lower electrode 230. In this case, the ground source GS may be connected to the upper electrode 220.

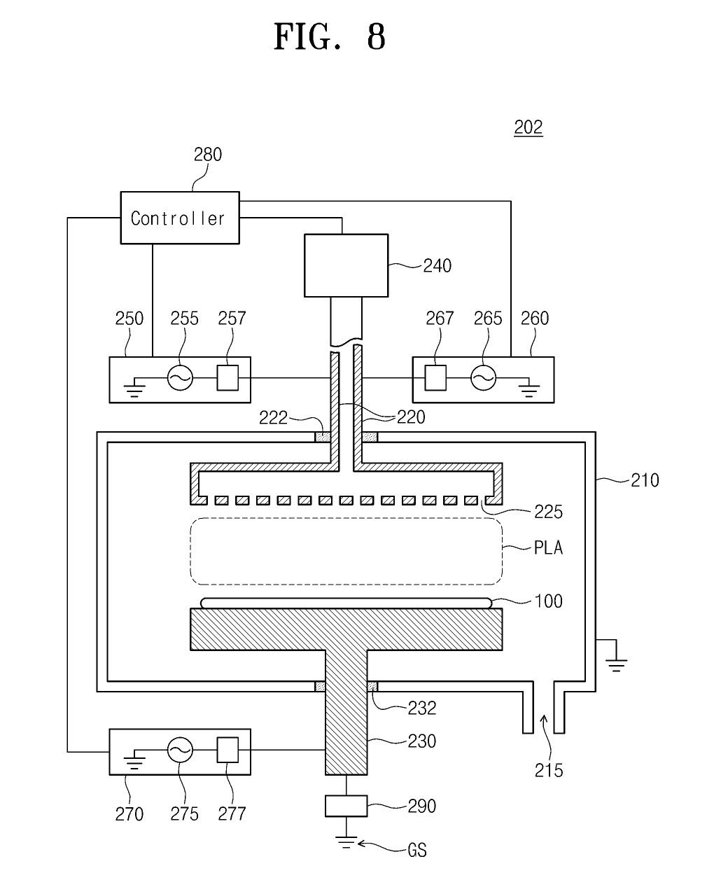

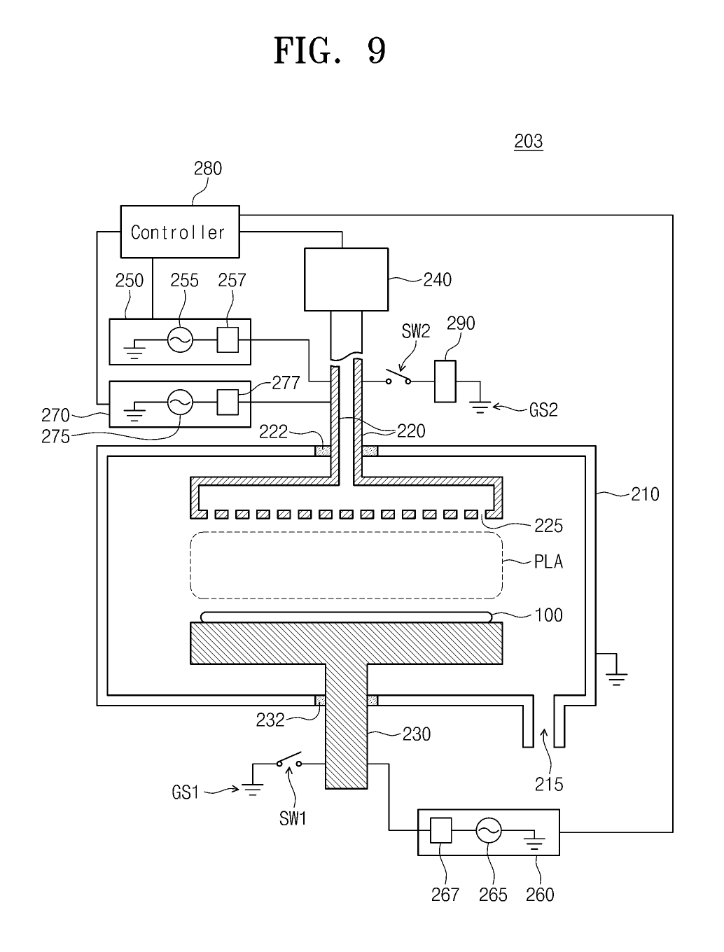

FIG. 8 is a schematic diagram illustrating a semiconductor manufacturing apparatus according to another exemplary embodiment.

Referring to FIG. 8, in a semiconductor manufacturing apparatus 202, the first and second high-frequency power units 250 and 260 may be connected to the upper electrode 220, and the low-frequency power unit 270 may be connected to the lower electrode 230. The ground source GS may be connected to the lower electrode 230. In other words, both the low-frequency power unit 270 and the ground source GS may be connected to the lower electrode 230. In this case, a high-pass filter 290 may be connected between the ground source GS and the lower electrode 230.

The high-pass filter 290 may pass the first and second high-frequency powers having the first and second high frequencies, respectively, but may substantially block the low-frequency power having the low frequency. Since the low-frequency power unit 270 and the ground source GS are ultimately connected to the lower electrode 230, this may lead to the low-frequency power unit 270 being connected directly to the ground source GS. However, since the high-pass filter 290 is connected between the ground source GS and the lower electrode 230, the low-frequency power may be applied to the lower electrode 230. In other words, the direct connection between the low-frequency power unit 270 and the ground source GS may be prevented by the high-pass filter 290. The high-pass filter 290 may include an RC circuit including a resistor and a capacitor, or an LC circuit including a resistor and a coil.

In other exemplary embodiments, the first and second high-frequency power units 250 and 260 may be connected to the lower electrode 230, and the low-frequency power unit 270 and the ground source GS may be connected to the upper electrode 220. In this case, the high-pass filter 290 may be connected between the ground source GS and the upper electrode 220.

FIG. 9 is a schematic diagram illustrating a semiconductor manufacturing apparatus according to another exemplary embodiment.

Referring to FIG. 9, in a semiconductor manufacturing apparatus 203, the first high-frequency power unit 250 and the low-frequency power unit 270 may be connected to the upper electrode 220, and the second high-frequency power unit 260 may be connected to the lower electrode 230. In this case, a first ground source GS1 may be coupled to the lower electrode 230, and a first switch SW1 may be connected between the first ground source GS1 and the lower electrode 230. In addition, a second ground source GS2 may be coupled to the upper electrode 220, and a second switch SW2 may be connected between the second ground source GS2 and the upper electrode 220.

Since the low-frequency power unit 270 is connected to the upper electrode 220, the high-pass filter 290 may be connected between the second switch SW2 and the second ground source GS2.

During the first CCP process using the first high-frequency power unit 250, the first switch SW1 may be turned-on to connect the lower electrode 230 to the first ground source GS1. At this time, the controller 280 interrupts the second high-frequency power of the second high-frequency power source 265, as described above. In addition, during the first CCP process, the second switch SW2 is turned-off to isolate the upper electrode 220 from the second ground source GS2.

During the second CCP process using the second high-frequency power unit 260, the second switch SW2 may be turned-on to connect the upper electrode 220 to the second ground source GS2. At this time, the controller 280 interrupts the first high-frequency power of the first high-frequency power source 255. In addition, during the second CCP process, the first switch SW1 is turned-off to isolate the lower electrode 230 from the first ground source GS1. In some exemplary embodiments, the low-frequency power of the low-frequency power source 275 may be applied to the upper electrode 220. In this case, the low-frequency power may be stably applied to the upper electrode 220 due to the high-pass filter 290.

Unlike the exemplary embodiment of FIG. 9, alternatively the first high-frequency power unit 250 and the low-frequency power unit 270 may be connected to the lower electrode 230, and the second high-frequency power unit 260 may be connected to the upper electrode 220. In this case, the high-pass filter 290 may be connected between the first switch SW1 and the first ground source GS1. In this exemplary embodiment, during the first CCP process, the second switch SW2 may be turned-on and the first switch SW1 may be turned-off. During the second CCP process, the first switch SW1 may be turned-on and the second switch SW2 may be turned-off.

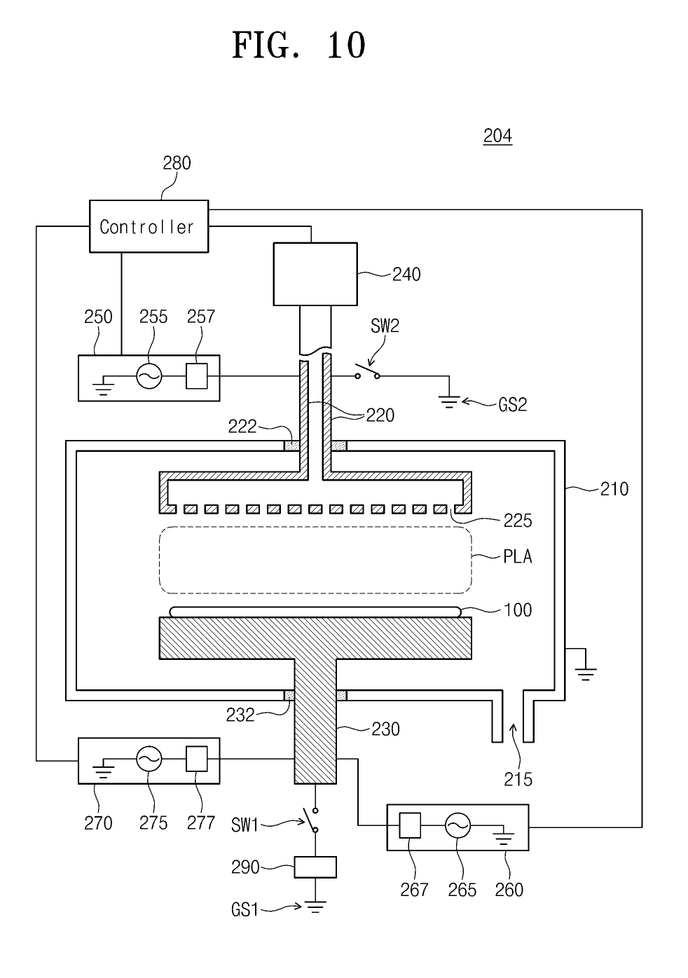

FIG. 10 is a schematic diagram illustrating a semiconductor manufacturing apparatus according to another exemplary embodiment.

Referring to FIG. 10, in a semiconductor manufacturing apparatus 204, the first high-frequency power unit 250 may be connected to the upper electrode 220, and the second high-frequency power unit 260 and the low-frequency power unit 270 may be connected to the lower electrode 230. In this case, the high-pass filter 290 may be connected between the first ground source GS1 and the first switch SW1 connected to the lower electrode 230. A method of operating the semiconductor manufacturing apparatus 204 may be the same as the method of operating the semiconductor manufacturing apparatus 203 of FIG. 9.

In still other exemplary embodiments, the first high-frequency power unit 250 may be connected to the lower electrode 230, and the second high-frequency power unit 260 and the low-frequency power unit 270 may be connected to the upper electrode 220. In this case, the high-pass filter 290 may be connected between the second ground source GS2 and the second switch SW2 connected to the upper electrode 220.

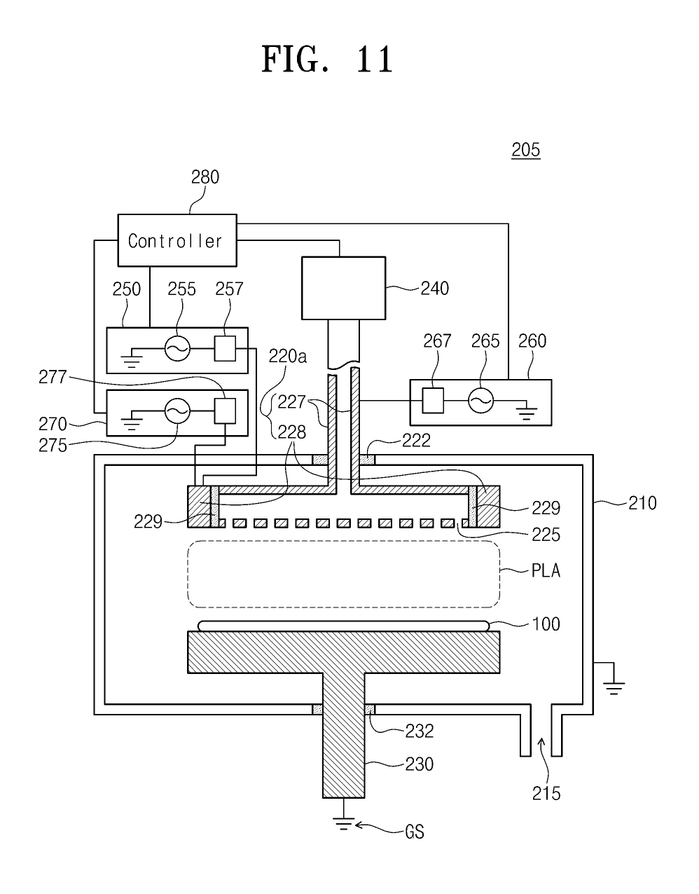

FIG. 11 is a schematic diagram illustrating a semiconductor manufacturing apparatus according to another exemplary embodiment.

Referring to FIG. 11, a semiconductor manufacturing apparatus 205 may include an upper electrode 220a including a first electrode 227 and a second electrode 228. The first electrode 227 may extend from the inside of the process chamber 210 to penetrate the top plate of the process chamber 210. In some exemplary embodiments, the first electrode 227 may be a shower head for supplying a process gas into the process chamber 210. The second electrode 228 may be disposed within the process chamber 210. The second electrode 228 may surround a sidewall of a portion, which is disposed within the process chamber 210, of the first electrode 227. The second electrode 228 may have a closed-loop shape such as a ring shape.

The second electrode 228 may be insulated from the first electrode 227. For example, a third insulator 229 may be disposed between the second electrode 228 and the first electrode 227.

In this exemplary embodiment, the first high-frequency power unit 250 may be connected to the second electrode 228, and the second high-frequency power unit 260 may be connected to a portion, which is disposed outside the process chamber 210, of the first electrode 227. In some exemplary embodiments, the first high-frequency power unit 250 may be connected to the second electrode 228 through a vacuum switch.

In this exemplary embodiment, the low-frequency power unit 270 may also be connected to the second electrode 228. The low-frequency power unit 270 may be connected to the second electrode 228 through the vacuum switch or an additional vacuum switch.

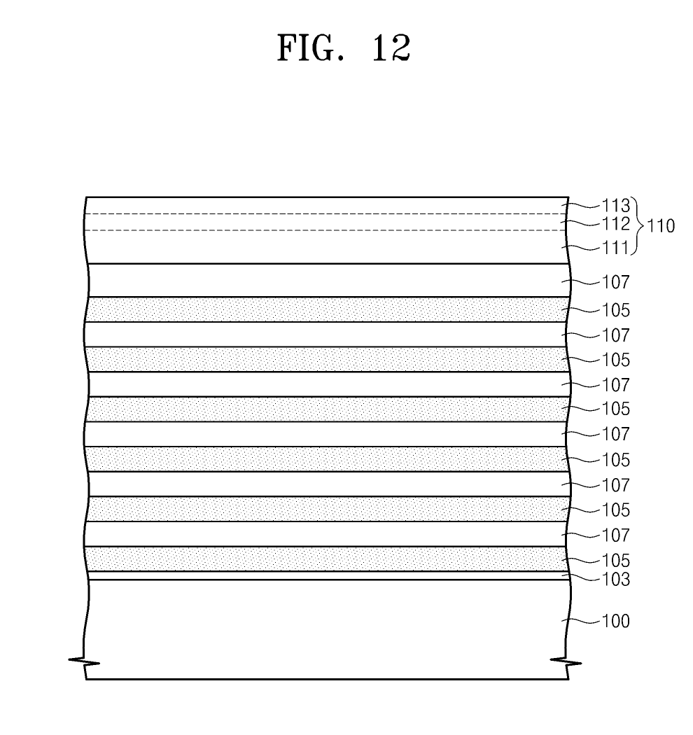

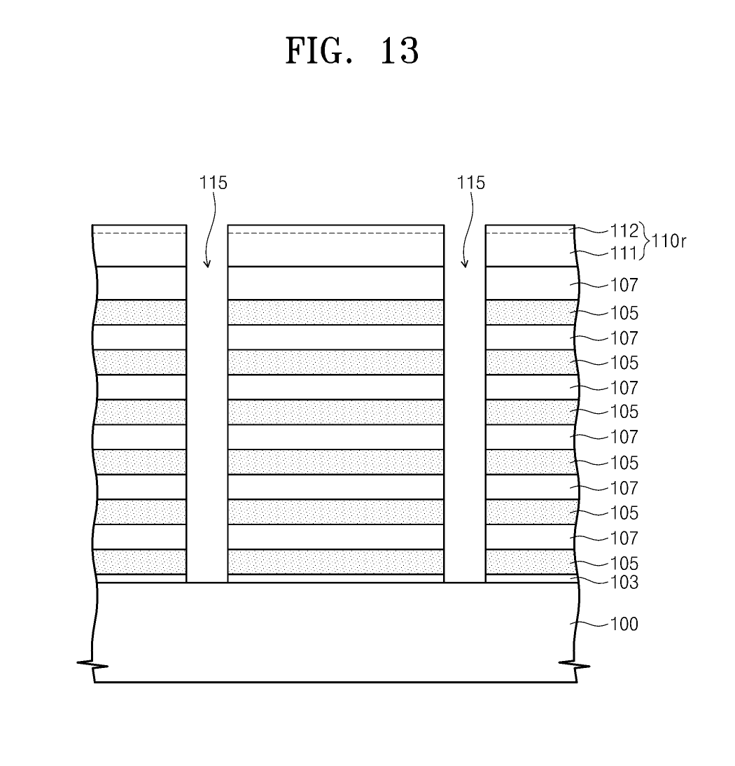

At least one of the semiconductor manufacturing apparatuses according to exemplary embodiments may be used in a method of manufacturing a semiconductor device having a three-dimensional structure. This will be described with reference to FIGS. 12 to 18.

FIGS. 12 to 18 are cross-sectional views illustrating another exemplary embodiment of a method of manufacturing a semiconductor device using a semiconductor manufacturing apparatus according to exemplary embodiments.

Referring to FIG. 12, sacrificial layers 105 and insulating layers 107 may be alternately and repeatedly deposited on a substrate 100. The sacrificial layers 105 and the insulating layers 107 may constitute a mold structure. The sacrificial layers 105 may be formed of a material having an etch selectivity with respect to the insulating layers 107. For example, the insulating layers 107 may be formed of silicon oxide layers, and the sacrificial layers 105 may be formed of silicon nitride layers. The sacrificial layers 105 and the insulating layers 107 may be formed by one of the semiconductor manufacturing apparatuses 200 to 205 described with reference to FIGS. 1 and 7 to 11. In some exemplary embodiments, each of the insulating layers 107 may be formed by the first CCP deposition process described with reference to FIG. 3, and each of the sacrificial layers 105 may be formed by the second CCP deposition process described with reference to FIG. 3. In other words, the second CCP deposition process and the first CCP deposition process may be alternately and repeatedly performed to form the sacrificial layers 105 and the insulating layers 107. At this time, the sacrificial layers 105 and the insulating layers 107 may be deposited in-situ in the process chamber 210. Alternatively, each of the insulating layers 107 may be formed using the second CCP deposition process and each of the sacrificial layers 105 may be formed using the first CCP deposition process

Since the sacrificial layers 105 are deposited by the second CCP deposition processes using the second high-frequency power, deposition rates of the sacrificial layers 105 may be increased. Thus, a process time of a semiconductor manufacturing process may be reduced and efficiency of the semiconductor manufacturing process may be improved. In addition, hydrogen contents of the sacrificial layers 105 may be reduced to improve reliability of the semiconductor device. Furthermore, the insulating layers 107 deposited by the first CCP deposition processes may have the compressive force, and the sacrificial layers 105 deposited by the second CCP deposition processes may have the tensile stress. Thus, the stresses of the sacrificial layers 105 and the insulating layers 107 may offset each other to relax a total stress of the mold structure. This means that the reliability of the semiconductor device may be further improved.

A buffer insulating layer 103 may be formed on the substrate 100 before the formation of the sacrificial layers 105 and the insulating layers 107. In some exemplary embodiments, the buffer insulating layer 103 may be formed of a thermal oxide layer.

In other exemplary embodiments, the buffer insulating layer 103 may be an oxide layer that is formed by a deposition process. In this case, the buffer insulating layer 103 may be formed by the first CCP deposition process. In other words, the first CCP deposition process and the second CCP deposition process may be alternately and repeatedly performed to deposit the buffer insulating layer 103, the sacrificial layers 105, and the insulating layers 107 in-situ in the process chamber 210.

However, the inventive concepts are not limited to the materials of the insulating layers 107 and the sacrificial layers 105 described above. In other words, the insulating layers 107 may be formed of at least one of other insulating materials, and the sacrificial layers 105 may be formed of at least one of other materials having an etch selectivity with respect to the insulating layers 107.

A hard mask layer 110 may be formed on the mold structure. In some exemplary embodiments, the hard mask layer 110 may be formed of an amorphous carbon layer. In this case, the hard mask layer 110 may be deposited by the first, second, and third CCP deposition processes described with reference to FIGS. 1 and 6. Thus, the hard mask layer 110 may include a lower layer 111, a middle layer 112, and an upper layer 113 which are sequentially stacked on the mold structure.

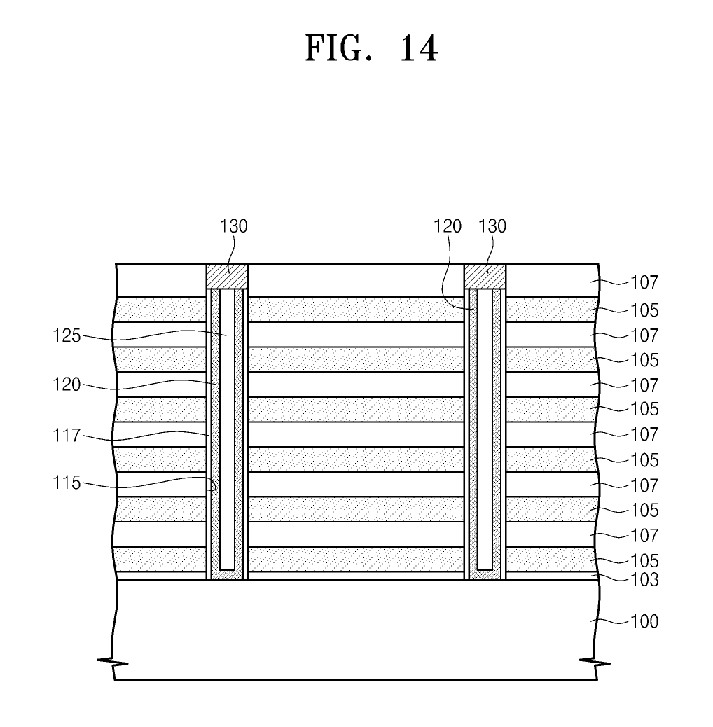

Referring to FIG. 13, the hard mask layer 110 may be patterned to form openings. Subsequently, the insulating layers 107, the sacrificial layers 105, and the buffer insulating layer 103 may be sequentially etched using the hard mask layer 110 as an etch mask to form channel holes 115 that expose the substrate 100. When the channel holes 115 are formed, at least the upper layer 113 (see FIG. 12) of the hard mask layer 110 may be removed but a portion 110r of the hard mask layer 110 may remain.

Referring to FIG. 14, the remaining hard mask layer 110r may be removed by, for example, an ashing process.

A vertical channel pattern 120 may be formed in each of the channel holes 115. The vertical channel pattern 120 may be connected to the substrate 100 and may include a semiconductor material. The vertical channel pattern 120 may be undoped or may be doped with dopants of which a conductivity type is the same as that of the substrate 100. In some exemplary embodiments, a first sub-data storage layer 117 may be formed on an inner sidewall of each of the channel holes 115 before the formation of the vertical channel pattern 120. In some exemplary embodiments, the vertical channel pattern 120 may have a hollow cylindrical shape. In this case, an inner space of the vertical channel pattern 120 may be filled with a filling insulation pattern 125. The filling insulation pattern 125 may be formed of, for example, silicon oxide.

A conductive pad 130 may be formed on the vertical channel pattern 120. For example, top ends of the vertical channel pattern 120, the filling insulation pattern 125 and the first sub-data storage layer 117 may be recessed, and the conductive pad 130 may be formed in the recessed region. The conductive pad 130 may include at least one of a doped semiconductor material doped with dopants (e.g., doped silicon), a metal (e.g., tungsten, titanium, and/or tantalum), or a conductive metal nitride (e.g., titanium nitride, tantalum nitride, and/or tungsten nitride).

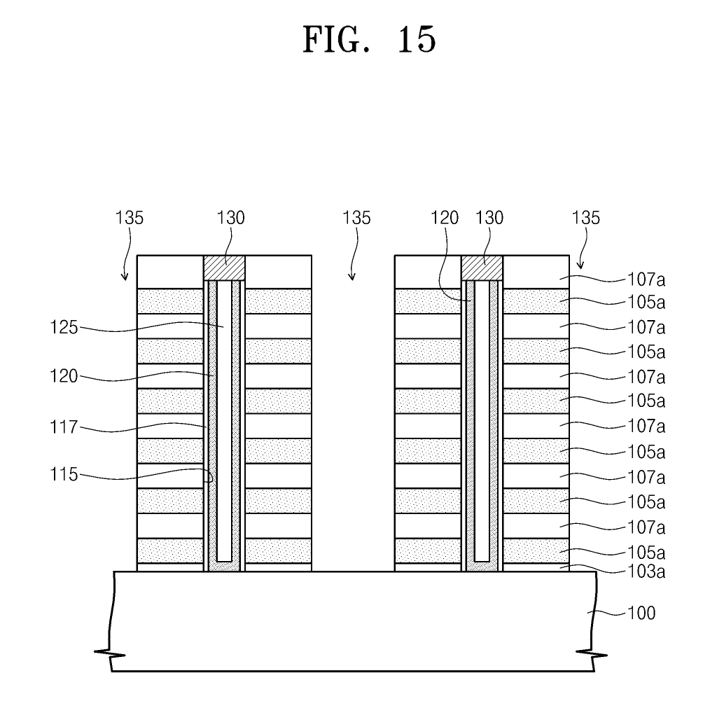

Referring to FIG. 15, the insulating layers 107, the sacrificial layers 105, and the buffer insulating layer 103 may be sequentially patterned to form trenches 135. A mold pattern may be formed between the trenches 135 that are adjacent to each other. The mold pattern may include sacrificial patterns 105a and insulating patterns 107a that are alternately stacked. In addition, the mold pattern may further include a buffer insulating pattern 103a. The trenches 135 may be laterally spaced apart from the channel holes 115. Thus, the channel holes 115 may penetrate the mold patterns.

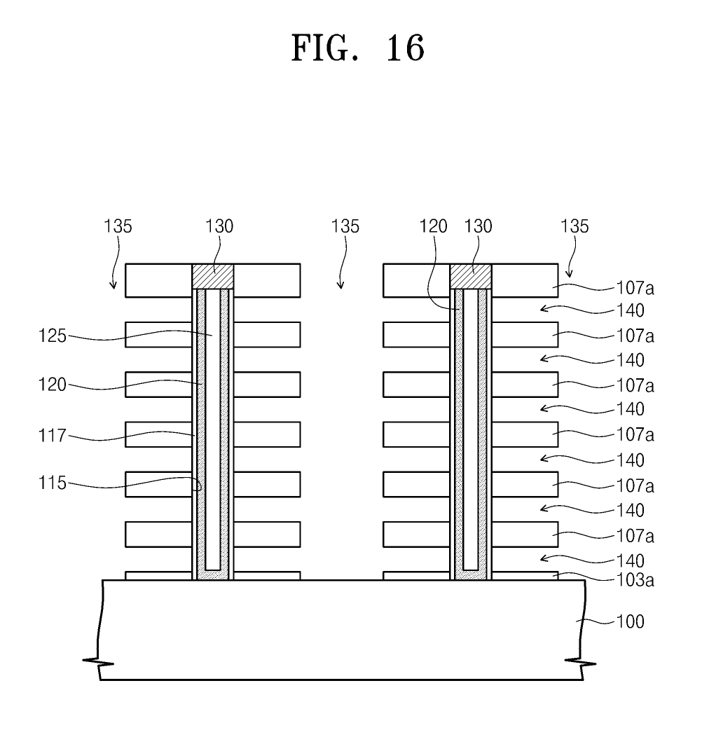

Referring to FIG. 16, the sacrificial patterns 105a exposed through the trenches 135 may be removed to form empty regions 140. The empty regions 140 may be formed between the insulating patterns 107a. The empty regions 140 may expose the first sub-data storage layer 117.

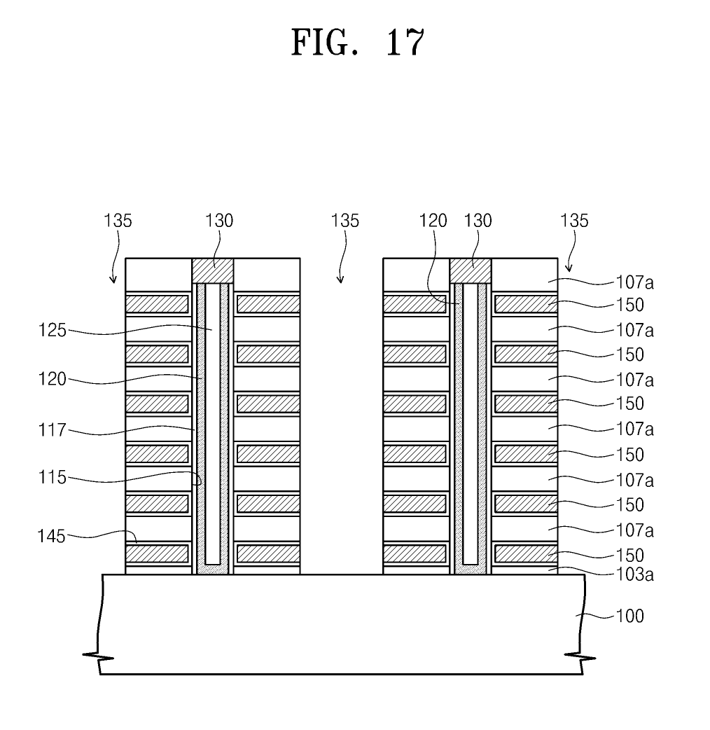

Referring to FIG. 17, a second sub-data storage layer 145 may be conformally formed on inner surfaces of the empty regions 140, and a conductive layer may be formed on the second sub-data storage layer 145 to fill the empty regions 140. The conductive layer disposed outside the empty regions 140 may be removed to form conductive patterns 150 in the empty regions 140, respectively. In some exemplary embodiments, the conductive patterns 150 may be gate electrodes. The second sub-data storage layer 145 disposed outside the empty regions 140 may also be removed when the conductive patterns 150 are formed.

The first and second sub-data storage layers 117 and 145 may constitute a data storage layer. The data storage layer may include a tunnel dielectric layer, a charge storage layer, and a blocking dielectric layer. In some exemplary embodiments, the blocking dielectric layer may include a barrier insulating layer and a high-k dielectric layer. An energy band gap of the barrier insulating layer may be greater than that of the high-k dielectric layer. A dielectric constant of the high-k dielectric layer may be higher than that of the tunnel dielectric layer. The first sub-data storage layer 117 may include at least the tunnel dielectric layer, and the second sub-data storage layer 145 may include at least a portion of the blocking dielectric layer. Here, any one of the first and second sub-data storage layers 117 and 145 may include the charge storage layer. In some exemplary embodiments, the first sub-data storage layer 117 may include the tunnel dielectric layer, the charge storage layer, and the barrier insulating layer, and the second sub-data storage layer 145 may include the high-k dielectric layer.

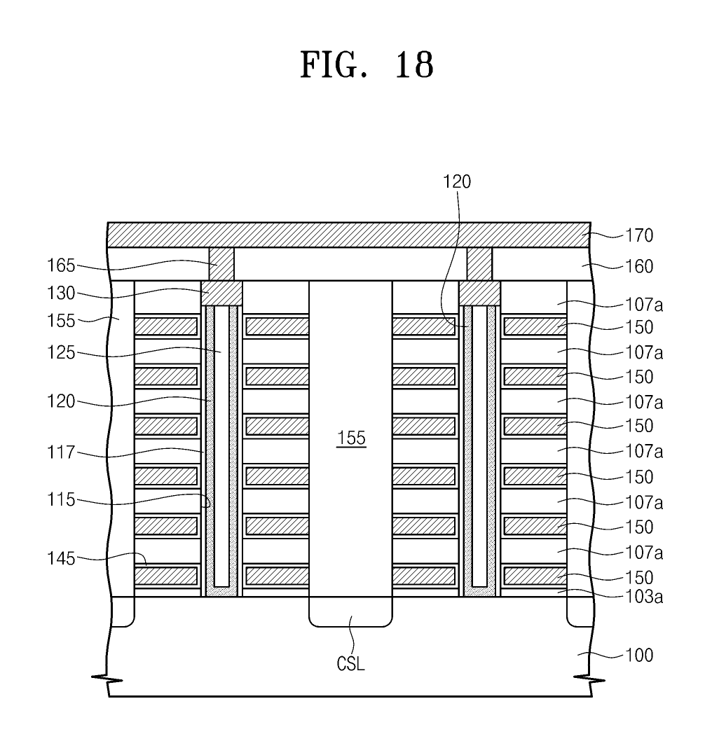

Referring to FIG. 18, dopants may be injected into the substrate 100 under each of the trenches 135 to form a common source line CSL. A device isolation layer (e.g., a silicon oxide layer) may be formed to fill the trenches 135, and the device isolation layer may be planarized to form device isolation patterns 155 in the trenches 135, respectively.

Next, an interlayer insulating layer 160 may be formed on the substrate 100, and contact plugs 165 may be formed to penetrate the interlayer insulating layer 160. The contact plugs 165 may be connected to the conductive pads 130, respectively. An interconnection 170 may be formed on the interlayer insulating layer 160 so as to be connected to the contact plugs 165. The interconnection 170 may be a bit line.

According to exemplary embodiments of the inventive concepts, the first and second CCP processes are performed using the first and second high-frequency powers, respectively, and the second high-frequency power is interrupted during the first CCP process. Thus, all of desired characteristics of the first and second CCP processes may be satisfied. This means that the efficiency and reliability of the manufacturing method may be improved and the manufacturing time of the semiconductor device may be reduced.

While the inventive concepts have been described with reference to certain exemplary embodiments, it will be apparent to those skilled in the art that various changes and modifications may be made without departing from the spirits and scopes of the inventive concepts. Therefore, it should be understood that the above exemplary embodiments are not limiting, but illustrative. Thus, the scopes of the inventive concepts are to be determined by the broadest permissible interpretation of the following claims and their equivalents, and shall not be restricted or limited by the foregoing description.

1. A semiconductor manufacturing apparatus comprising:
a process chamber including an inner space;
a lower electrode disposed in the process chamber and having a top surface on which a substrate is loaded;
an upper electrode disposed over the lower electrode in the process chamber;
a first high-frequency power source connected to one of the lower electrode and the upper electrode, and configured to generate first high-frequency power used to perform a first capacitively coupled plasma (CCP) process;
a second high-frequency power source connected to one of the lower electrode and the upper electrode, configured to generate a second high-frequency power used to perform a second CCP process; and
a controller connected to the first high-frequency power source and the second high-frequency power source, and configured to control the second high-frequency power source to interrupt the second high-frequency power during the first CCP process.

2. The semiconductor manufacturing apparatus of claim 1, wherein the controller is configured to control the first high-frequency power source to interrupt the first high-frequency power during the second CCP process.

3. The semiconductor manufacturing apparatus of claim 1, wherein the first high-frequency power source is configured to generate the first high-frequency power at a first high frequency, the second high-frequency power source is configured to generate the second high-frequency power at a second high frequency, and
the first high frequency is different from the second high frequency.

4. The semiconductor manufacturing apparatus of claim 3, wherein each of the first high frequency and the second high frequency is greater than or equal to 5 MHz.

5. The semiconductor manufacturing apparatus of claim 1, further comprising:
a low-frequency power source connected to the controller and one of the lower electrode and the upper electrode,
wherein the first high-frequency power source is configured to generate the first high-frequency power at a first high frequency,
the second high-frequency power source is configured to generate the second high-frequency power at a second high frequency, and
the low-frequency power source is configured to generate low-frequency power at a frequency that is smaller than frequencies of the first and second high-frequency powers.

6. The semiconductor manufacturing apparatus of claim 5, wherein one of the lower electrode and the upper electrode is connected to the first high-frequency power source and the second high-frequency power source,
the semiconductor manufacturing apparatus further comprising a ground source connected to the other one of the lower electrode and the upper electrode.

7. The semiconductor manufacturing apparatus of claim 6, wherein the low-frequency power source is connected to the other one of the lower electrode and the upper electrode,
the semiconductor manufacturing apparatus further comprising a high-pass filter connected between the ground source and the other one of the lower electrode and the upper electrode,
wherein the high-pass filter is configured to pass the first high-frequency power and the second high-frequency power and substantially block the low-frequency power.

8. The semiconductor manufacturing apparatus of claim 5, wherein one of the lower electrode and the upper electrode is connected to the first high-frequency power source, and the other one of the lower electrode and the upper electrode is connected to the second high-frequency power source,
the semiconductor manufacturing apparatus further comprising:
a first ground source;
a first switch connected between the first ground source and the lower electrode;
a second ground source;
a second switch connected between the second ground source and the upper electrode; and
a high-pass filter connected between the first ground source and the first switch, or between the second ground source and the second switch,
wherein the low-frequency power source is connected to the one of the lower electrode and the upper electrode that is coupled to the high-pass filter, and
the high-pass filter is configured to pass the first high-frequency power and the second high-frequency power and substantially block the low-frequency power.

9. The semiconductor manufacturing apparatus of claim 5, wherein the process chamber comprises a top plate, and the upper electrode comprises:
a first electrode extending from the inner space of the process chamber to an outside of the process chamber, the first electrode penetrating the top plate such that a portion of the first electrode is disposed in the inner space and a portion of the first electrode is disposed outside of the process chamber; and
a second electrode surrounding a sidewall of the portion of the first electrode that is disposed in the inner space
wherein the second electrode is insulated from the first electrode,
the first high-frequency power source is connected to the second electrode, and
the second high-frequency power source is connected to the portion of the first electrode disposed outside the process chamber.

10. The semiconductor manufacturing apparatus of claim 5, wherein the low-frequency power is used during the first CCP process or the second CCP process.

11. The semiconductor manufacturing apparatus of claim 5, wherein the low-frequency power and one of the first high-frequency power and the second high-frequency power are used to perform a third CCP process.

12. The semiconductor manufacturing apparatus of claim 1, wherein the semiconductor manufacturing apparatus is configured to perform the first CCP process and the second CCP process in-situ in the process chamber.

13. The semiconductor manufacturing apparatus of claim 1, wherein the first CCP process is a first CCP deposition process for depositing a first layer at a first deposition rate,
the second CCP process is a second CCP deposition process for depositing a second layer at a second deposition rate, and
the first deposition rate is different from the second deposition rate.

14-20. (canceled)

21. A semiconductor manufacturing apparatus comprising:
a process chamber;
a first electrode disposed in the process chamber;
a first high-frequency power source connected to the first electrode and configured to generate a first high-frequency power used to perform a first capacitively coupled plasma (CCP) process inside the process chamber;
a second high-frequency power source connected to the first electrode and configured to generate a second high-frequency power used to perform a second CCP process inside the process chamber; and
a controller that is electrically connected to the first high-frequency power source and the second high-frequency power source and configured to control the second high-frequency power source to interrupt the second high-frequency power during the first CCP process.

22. The semiconductor manufacturing apparatus of claim 21, wherein the controller is configured to control the first high-frequency power source to interrupt the first high-frequency power source during the second CCP process.

23. The semiconductor manufacturing apparatus of claim 21, wherein the controller shuts off the second high-frequency power source during the first CCP process.

24. The semiconductor manufacturing apparatus of claim 21, wherein the controller controls the second high-frequency power source to substantially reduce the second high-frequency power during the first CCP process.

25. The semiconductor manufacturing apparatus of claim 21, further comprising a low frequency power source that is electrically connected to the electrode and to the controller, and configured to generate a low frequency power that is smaller than the first high frequency power and smaller than the second high frequency power.

26. The semiconductor manufacturing apparatus of claim 25, further comprising a second electrode configured to support a substrate to be subjected to the first CCP process.

27. The semiconductor manufacturing apparatus of claim 21, further comprising a second electrode and a low frequency power source that is electrically connected to the second electrode and to the controller, and configured to generate a low frequency power that is smaller than the first high frequency power and smaller than the second high frequency power.
